(19) United States
(12) Patent Application Publication
(10) Pub. No.: US 2011/0073353 A1
(43) Pub. Date: Mar. 31, 2011

(54) CONDUCTIVE FABRIC AND METHOD FOR FORMING THE SAME

(75) Inventors: James LEE, Taipei (TW); Hong Hsu HUANG, Taipei (TW)

(73) Assignees: TEX-RAY INDUSTRIAL CO., LTD., Taipei (TW); KING'S METAL FIBER TECHNOLOGIES CO., LTD., Taipei (TW)

(21) Appl. No.: 12/569,882

(22) Filed: Sep. 29, 2009

(51) Int. Cl. H05K 1/00; B32B 5/26; D03D 15/00

(52) U.S. Cl. 174/254; 442/239; 442/190; 139/408; 139/425 R

(57) ABSTRACT

A conductive fabric and a method for forming the same are provided. The conductive fabric comprises a first layer and a second layer. The first layer has at least one first conductive thread and a plurality of first non-conductive threads. The at least one first conductive thread is woven within the plurality of first non-conductive threads. The second layer has at least one second conductive thread and a plurality of second non-conductive threads. The at least one second conductive thread is woven within the plurality of second non-conductive threads. The first layer is woven with the second layer and insulated from the second layer so that an electronic component can be attached to and electrically connect to the at least one first conductive thread of the first layer and the at least one second conductive thread of the second layer.

### FIELD

The present invention relates to a conductive fabric and a method for forming the same. More particularly, the present invention relates to a layered conductive fabric and a method for forming the same.

### BACKGROUND

Fabrics in modern life are mostly used for being woven into normal clothing. Those fabrics have no additional function except for keeping warm and pursuing fashion. Recently, with the rapid growth of technology, more functions of the fabrics have been developed to increase the convenience of human life. For example, some of the fabrics are formed with some electronic components being attached thereon. Therefore, the clothing made of those fabrics with electronic components can be applied to many new fields. For example, LED lights can be used as indicators on the clothing for showing other people the ongoing direction or other applications.

However, it is complicated to attach the electronic components to the fabrics and detrimental to mass production accordingly. Moreover, one of the most important issues for those fabrics with electronic components attached thereon is to develop appropriate structures for insulation. Specifically, the fabrics must be conductive for those electronic components. Therefore, if the circuits are not insulted completely, those electronic components would be easily short with the human body and result in injury to the one who wear the clothing made of those fabrics. Accordingly, a better structure and manufacturing method for conductive fabrics is essentially needed.

### SUMMARY

The present invention addresses the above needs by providing a conductive fabric and a method for forming the same. On account of a layered structure of the conductive fabric, the circuits of the fabrics can work well without causing any short circuit so that an electrical component can be attached onto it and function as well.

An objective of certain embodiments of the present invention is to provide a conductive fabric. The conductive fabric comprises a first layer and a second layer. The first layer has at least one first conductive thread and a plurality of first non-conductive threads. The at least one first conductive thread is woven within the plurality of first non-conductive threads. The second layer has at least one second conductive thread and a plurality of second non-conductive threads. The at least one second conductive thread is woven within the plurality of second non-conductive threads. The first layer is woven with the second layer and insulated from the second layer so that an electronic component can be attached to and electrically connect to the at least one first conductive thread of the first layer and the at least one second conductive thread of the second layer.

Another objective of certain embodiments of the invention is to provide a method for forming a conductive fabric. The method comprises: weaving at least one first conductive thread within a plurality of first non-conductive threads to form a first layer with at least one first cored yarn; weaving at least one second conductive thread within a plurality of second non-conductive threads to form a second layer with at least one second cored yarn; and weaving the first layer and the second layer with a plurality of third non-conductive threads.

Yet a further objective of certain embodiments of the invention is to provide a fabric circuit. The fabric circuit comprises at least one electronic component and a conductive fabric. The conductive fabric comprises a first layer and a second layer. The first layer has at least one first conductive thread and a plurality of first non-conductive threads, wherein the at least one first conductive thread is woven within the plurality of first non-conductive threads. The second layer has at least one second conductive thread and a plurality of second non-conductive threads. The at least one second conductive thread is woven within the plurality of second non-conductive threads. The first layer is woven with the second layer and insulated from the second layer so that an electronic component can be attached to and electrically connect to the at least one first conductive thread of the first layer and the at least one second conductive thread of the second layer. The at least one electronic component is attached to the conductive fabric and electrically connects to the at least one first conductive thread and the at least one second conductive thread.

The detailed technology and preferred embodiments implemented for the subject invention are described in the following paragraphs accompanying the appended drawings for people skilled in this field to well appreciate the features of the claimed invention. It is understood that the features mentioned hereinbefore and those to be commented on hereinafter may be used not only in the specified combinations, but also in other combinations or in isolation, without departing from the scope of the present invention.

### BRIEF DESCRIPTION OF THE DRAWINGS

FIG. 1A is a schematic view of a first example embodiment of the present invention;

FIG. 1B is a schematic view of a first layer of an example embodiment of the present invention;

FIG. 1C is a schematic view of a second layer of an example embodiment of the present invention;

FIG. 1D is a cross-section view of the first layer from A to A′ in FIG. 1B;

FIG. 1E is a cross-section view of the second layer from B to B′ in FIG. 1C;

FIG. 1F is a cross-section view of a fabric circuit 1 from A to A′ in FIG. 1A;

FIG. 1G is a cross-section view of the fabric circuit from B to B′ in FIG. 1A;

FIG. 2A is a schematic view of a second example embodiment of the present invention;

FIG. 2B is a cross-section view of a fabric circuit 1′ from C to C′ in FIG. 2A;

FIG. 3A is a schematic view of a third example embodiment of the present invention;

FIG. 3B is a schematic view of a fourth example embodiment of the present invention;

FIG. 4 is a schematic view of a fifth example embodiment of the present invention; and

FIG. 5 is a flowchart of a sixth example embodiment of the present invention.

While the invention is amenable to various modifications and alternative forms, specifics thereof have been shown by way of example in the drawings and will be described in detail. It should be understood, however, that the intention is not to limit the invention to the particular example embodiments described. On the contrary, the invention is to cover all modifications, equivalents, and alternatives falling within the spirit and scope of the invention as defined by the appended claims.

### DETAILED DESCRIPTION

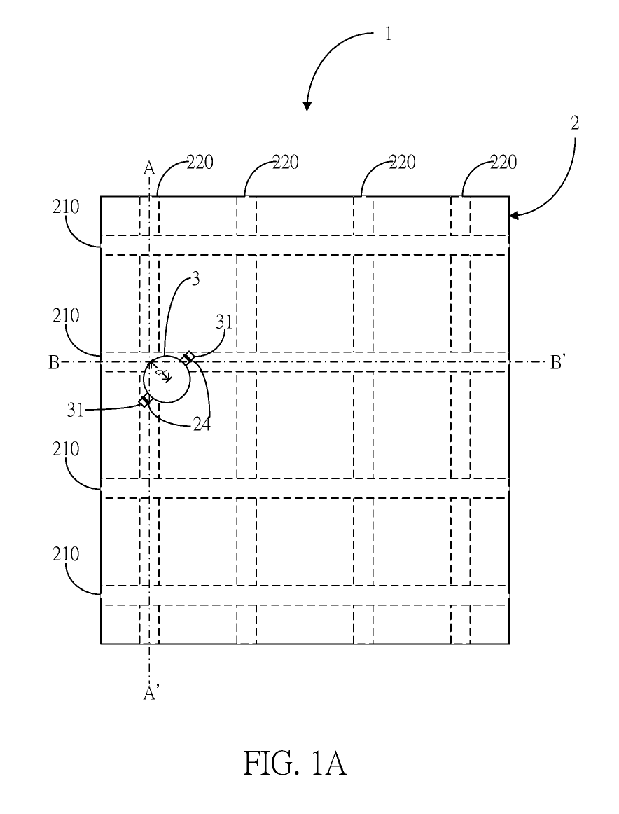

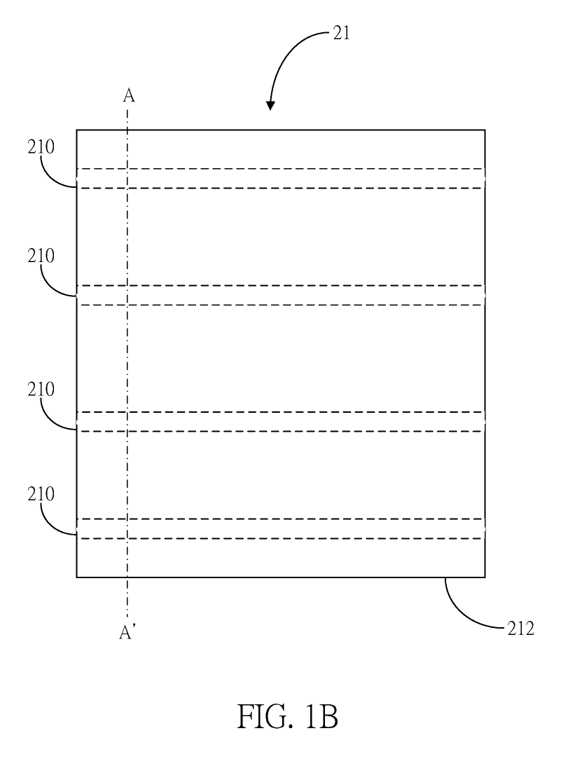

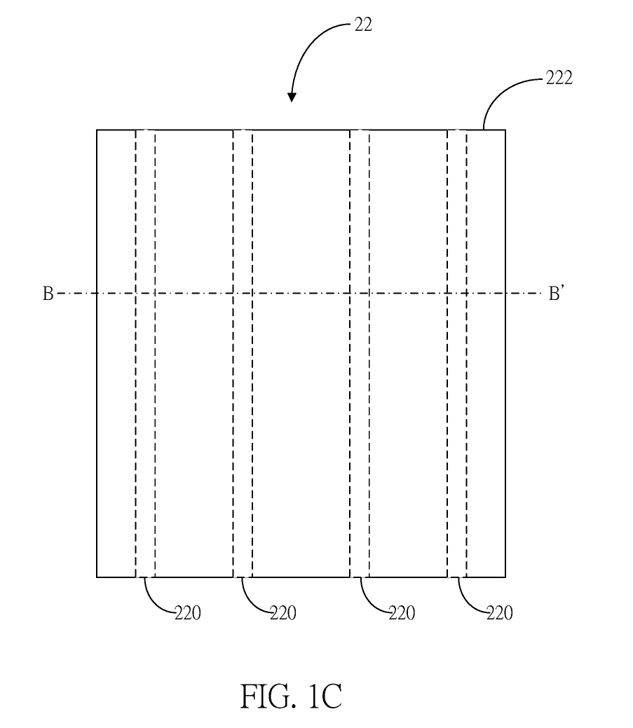

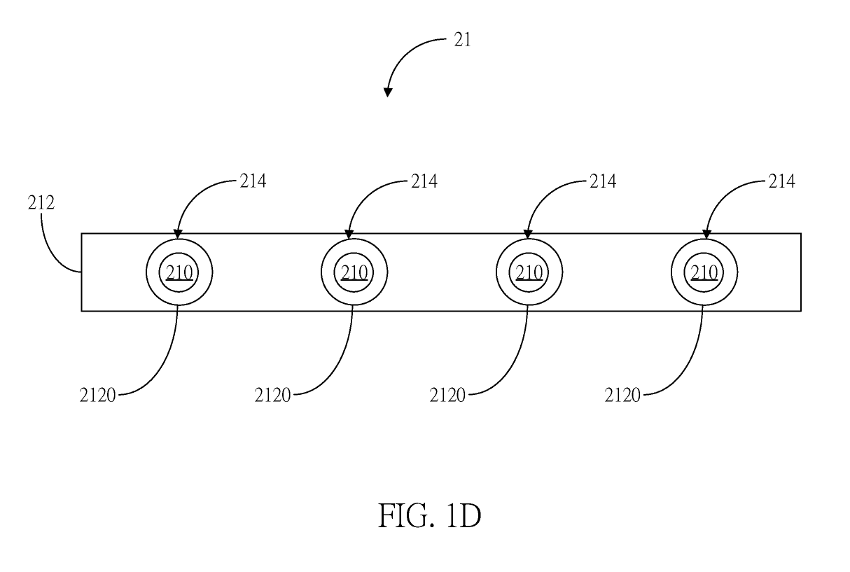

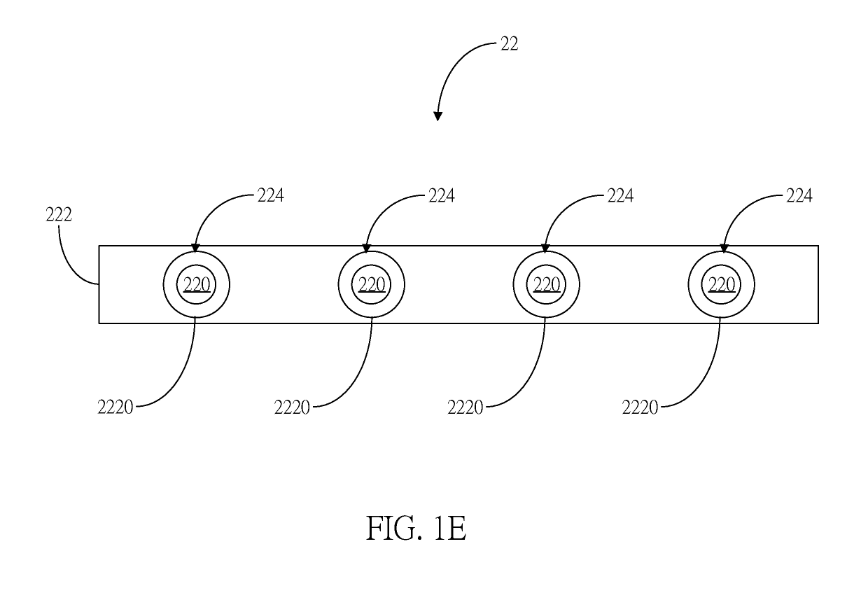

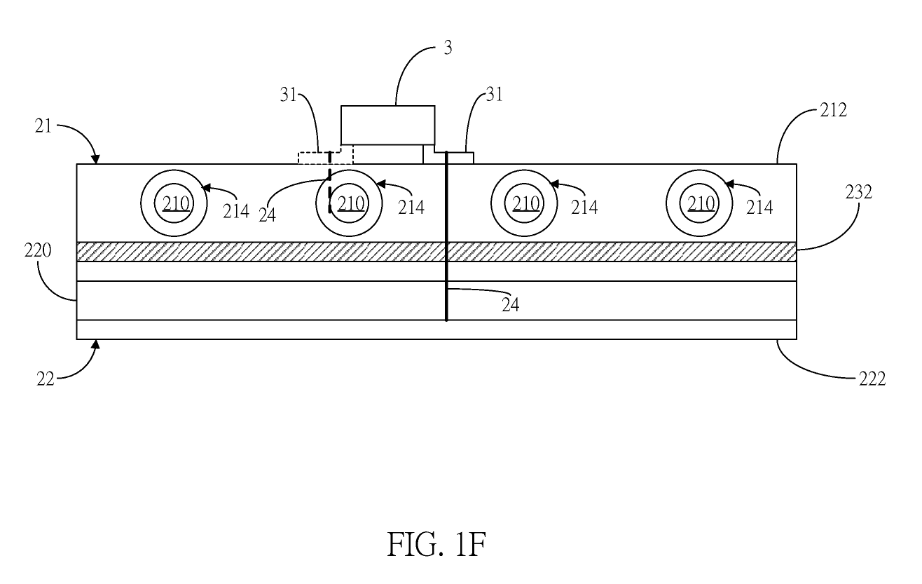

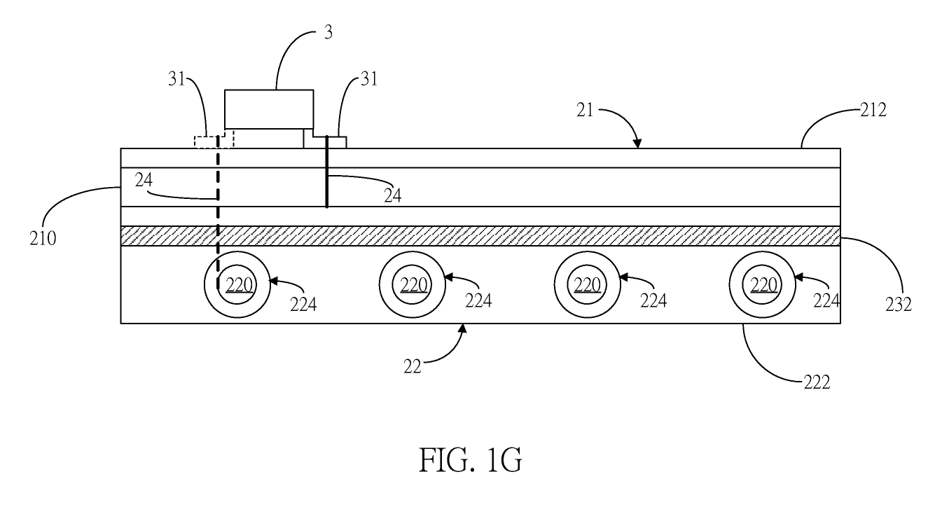

Referring to FIG. 1A, it shows a fabric circuit 1 of a first embodiment of the present invention. The fabric circuit 1 can be integrated into one portion of any conventional fabrics or cloth to broaden the original functions thereof. Specifically, the fabric circuit 1 comprises a conductive fabric 2 and at least one electrical component 3 attached on the conductive fabric 2. The conductive fabric 2 of this invention basically is a fabric capable of electrically connecting with any electrical component, such as light emitting diodes (LEDs), chips, or the like.

Referring to FIG. 1B and FIG. 1C simultaneously the conductive fabric 2 comprises a first layer 21 and a second layer 22. The first layer 21 has, for example, but not limited to, four first conductive threads 210 and a plurality of first non-conductive threads 212. The first conductive threads 210 are flexible and woven within the first non-conductive threads 212. Similarly, the second layer 22 has, for example, but not limited to, four second conductive threads 220 and a plurality of second non-conductive threads 222. The second conductive threads 220 are flexible and woven within the second non-conductive threads 222.

It should be noted that the first conductive threads 210 and the second conductive threads 220 are made of any conductive fibers with electric conductivity, for example, but not limited to, stainless steel fibers, carbon fibers, sputtered silver, or their combinations. Moreover, the first conductive threads 210 and the second conductive threads 220 are flexible enough for be woven with any conventional fabrics or cloth. Further, the first non-conductive threads 212 of the first layer 21 and the second non-conductive threads 222 of the second layer 22 are all made of any non-conductive materials, for example, polyester, PET, cotton, pure polyurethane polymer, or their combinations.

More details of the first layer 21 are shown in FIG. 1D which is a cross-section view of the first layer 21 from A to A′ in FIG. 1B. It can be seen clearly that the first non-conductive threads 212 are formed in a layered structure. Preferably, one portion of the first non-conductive threads 212 comprises a plurality of first covering portions 2120. In this embodiment, four first covering portions 2120 existed in the layered structure and each of the first conductive threads 210 is covered by the corresponding first covering portion 2120 to form a first cored yarn 214. Then, the first cored yarns 214 would be used to be woven with another portion of the first non-conductive threads 212 together to form the first layer 21. It is noted that the cored yarn is a basic conductive unit of the conductive fabric with a good insulation property, and the cored yarn is flexible and could be easily wound around a shuttle so that the cord yarn could be easily adopted in any conventional textile machinery.

Similarly, FIG. 1E is the cross-section view of the second layer 22 from B to B′ in FIG. 1C. FIG. 1E illustrates the details of the second layer 22 just the same as the details of the first layer 21. The second non-conductive threads 222 are formed in a layer structure as well and one portion of the second non-conductive threads 222 comprise four second covering portions 2220 covering the four second conductive threads 220 respectively and form four second cored yarn 224 existed therein. Then, the second cored yarns 224 would be used to be woven with another portion of the second non-conductive threads 222 together to form the second layer 22.

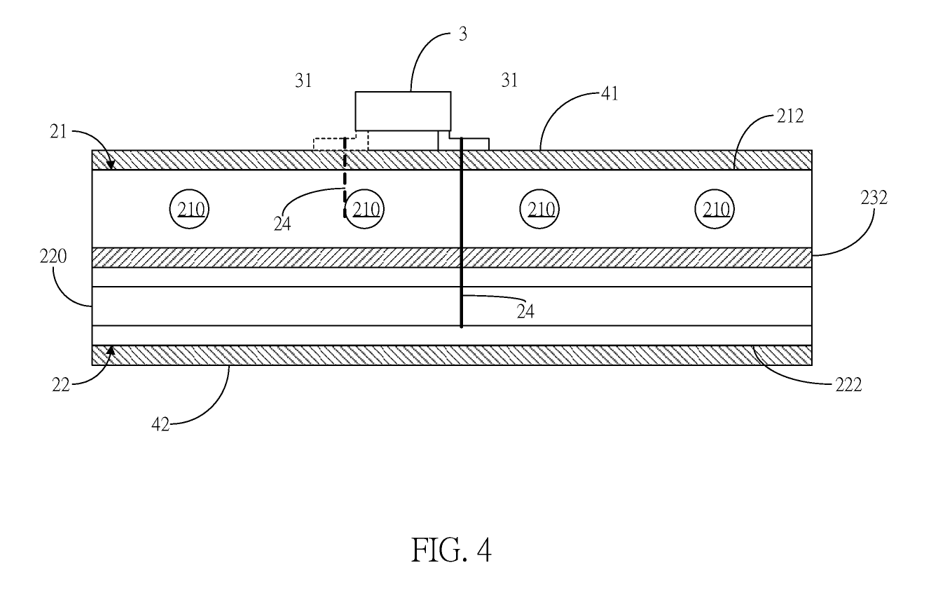

As described above, the first and the second conductive threads 210, 220 are woven or knit within the first and the second non-conductive threads 212, 222 to form the first layer 21 and the second layer 22 respectively. Moreover, other manufacturing methods would be applied to form the layered structure, such as embroidery or printing, or the like. Furthermore, the first layer 21 could be woven or embroidery with the second layer 22 together to form the fabric circuit 1 wherein the first layer 21 is insulated from the second layer 22. To enhance the insulation between the fabric circuit 1 with the human body, the conductive fabric 2 can further comprise at least one insulation layer for covering one of the first layer 21 and the second layer 22. As the preferred embodiment shown in FIG. 4, there are two insulation layers 41, 42 for covering the first layer 21 and the second layer 22 individually. The insulation layer could be coated or printed or adhesive to the first and the second layers 21, 22 by any non-conductive material. More details will be described in the following.

In a preferred embodiment, the conductive fabric 2 further comprises a plurality of third non-conductive threads 232 for weaving the first layer 21 and the second layer 22 together and insulating therebetween, as shown in FIG. 1F and FIG. 1G which are the cross-section views of the fabric circuit 1 in FIG. 1A. Particularly, the third non-conductive threads 232 could be formed as a layered structure between the first layer 21 and the second layer 22. The third non-conductive threads 232 are made of any non-conductive material, for example, polyester, PET, cotton, pure polyurethane polymer, or their combinations, so that the first layer 21 would be completely insulated from the second layer 22.

Furthermore, in this embodiment, the first layer 21 and the second layer 22 are woven together as mentioned above while the first cored yarns 214 and the second cored yarns 224 in the conductive fabric 2 are configured in warps and wefts form as shown in FIG. 1A. Therefore, there are many junctions formed by intersecting the first cored yarns 214 and the second cored yarns 224. The junctions distributed on the conductive fabric 2 are arranged in a matrix or an array or any other configurations.

FIGS. 1A, 1F and 1G illustrate a top view and two cross-section views of the fabric circuit 1. The electronic component 3 can be attached to a position adjacent to any junction of the fabric circuit 1. Specifically, the electronic component 3 has two leads 31 which are used for being attached onto the conductive fabric 2. Particularly, two conductive sewing threads 24 are used for sewing the leads 31 of the electronic component 3 onto one position which has a small offset d with a specific junction of the conductive fabric 2, and each of the leads 31 of the electronic component 3 electrically connects to one of the first conductive threads 210 and one of the second conductive threads 220 respectively near the junction. Similarly, the conductive sewing threads 24 are made of any conductive fibers with electric conductivity, for example, but not limited to, stainless steel fibers, carbon fibers, sputtered silver, or their combinations.

Similar with sewing buttons onto cloth, the electronic component 3 could be sewn onto the conductive fabric 2 by any conventional sewing machine. Therefore, both the conductive fabric 2 and the fabric circuit 1 can be manufactured by any conventional textile machinery and/or sewing machine in a mass production manner.

The electronic component 3 can be detachably attached to and electrically connect to one of the first conductive threads 210 of the first layer 21 and one of the second conductive threads 220 of the second layer 22 systematically, and the electronic component 3 can function well when the first conductive threads 210 and the second conductive threads 220 are electrically connected to the power system (not shown). Moreover, when the fabric circuit 1 is arranged in a matrix circuit, the electronic components 3, such as LEDs, can be driven by any conventional control code for different specific applications, such as entertainments, indicating, signaling. It should be noted that the sewing threads 24 can electrically connect the first and the second conductive threads 210, 220 with the leads of the electronic component 3 directly driven by the sewing machine needle puncturing through the first layer 21 and the second layer 22 several times.

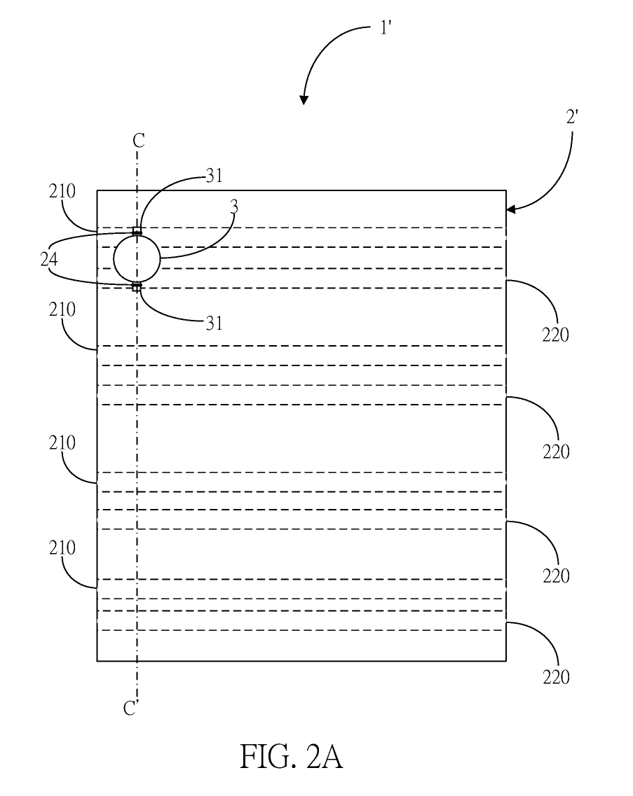

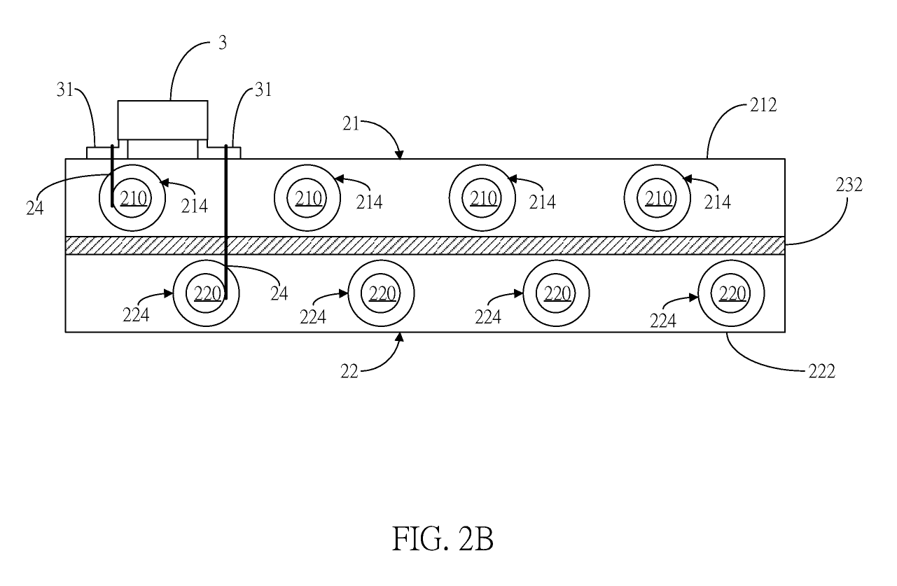

FIG. 2A and FIG. 2B illustrate a fabric circuit 1′ of a second embodiment. In this embodiment, the first cored yarns 214 of the first layer 21 and the second cored yarns 224 of the second layer 22 are woven in parallel. The other features of the fabric circuit 1′ are similar with those of the fabric circuit 1. Hence, the details of the structure of the fabric circuit 1′ will not be further described.

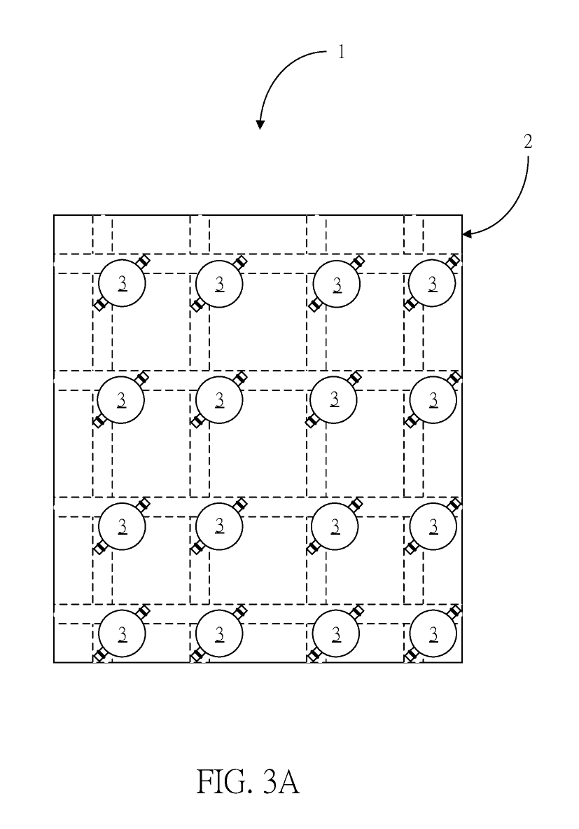

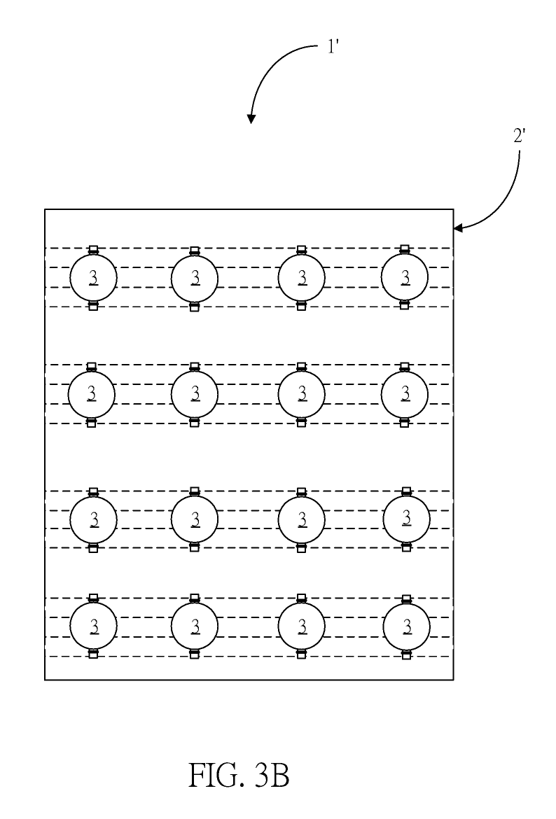

Based on the disclosure above, another two example fabric matrixes can be accomplished. FIG. 3A and FIG. 3B, illustrate a third example embodiment and a fourth example embodiment of aspects of this invention respectively. A plurality of electronic components 3 are attached to each position adjacent to the junction of the fabric circuit 1 and the fabric circuit 1′. In certain embodiments, if the electronic components 3 comprise several LEDs, the different lighting patterns on the fabric circuit 1 and the fabric circuit 1′ can be accomplished.

A fifth example embodiment of aspects of the present invention is illustrated in FIG. 4. The conductive fabric 2 comprises two insulation layers 41, 42 for covering the first layer 21 and the second layer 22 individually. The other elements are the same with those described in the aforesaid. The two insulation layers 41, 42 are used to enhance the insulation between the fabric circuit 1 and the human body. The other details of this embodiment are similar with the abovementioned.

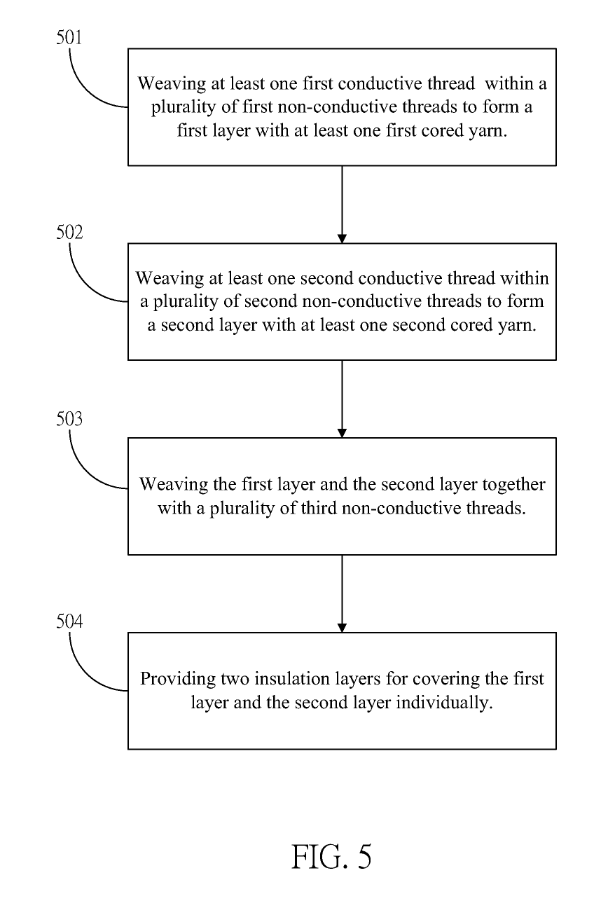

A sixth example embodiment of aspects of the present invention is a method for forming a conductive fabric which is similar to the conductive fabrics 2, 2′ as described above. Referring to FIG. 5, a flowchart of an example method according to an embodiment of the present invention is provided. In step 501, at least one first conductive thread is woven within a plurality of first non-conductive threads to form a first layer with at least one first cored yarn. Particularly, some of the first non-conductive threads are used for covering the at least one first conductive thread to form the at least one first cored yarn. And if there is more than one first cored yarn, rests of the first non-conductive threads are then used for weaving the first cored yarns together.

In step 502, at least one second conductive thread is woven within a plurality of second non-conductive threads to form a second layer with at least one second cored yarn. Similarly, some of the second non-conductive threads are used for covering the at least one second conductive thread to form the at least one second cored yarn. If there is more than one second cored yarn, rests of the second non-conductive threads are then used for weaving the second cored yarns together.

In step 503, the first layer and the second layer are woven together with a plurality of third non-conductive threads. Specifically, the third non-conductive threads are woven into a layer between the first layer and the second layer, and then weaving the first layer and the second layer together at the same time.

Finally, step 504 is optionally for providing two insulation layers for covering the first layer and the second layer individually. Similar to the third non-conductive threads which are used for insulating and weaving the first layer and the second layer, the two insulation layers can be woven onto the first layer and the second layer respectively.

The present invention may be embodied in other specific forms without departing from the spirit or essential attributes thereof, and it is, therefore, desired that the present disclosure and embodiments be considered in all respects as illustrative and not restrictive. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A conductive fabric, comprising:
a first layer, having at least one first conductive thread and a plurality of first non-conductive threads, wherein the at least one first conductive thread is woven within the plurality of first non-conductive threads; and
a second layer, having at least one second conductive thread and a plurality of second non-conductive threads, wherein the at least one second conductive thread is woven within the plurality of second non-conductive threads;
wherein the first layer is woven with the second layer and insulated from the second layer so that an electronic component can be attached to and electrically connect to the at least one first conductive thread of the first layer and the at least one second conductive thread of the second layer respectively.

2. The conductive fabric of claim 1, wherein the first non-conductive threads comprise a first covering portion, the at least one first conductive thread is covered by the first covering portion to form at least one first cored yarn.

3. The conductive fabric of claim 2, wherein the second non-conductive threads comprise a second covering portion, the at least one second conductive thread is covered by the second covering portion to form at least one second cored yarn.

4. The conductive fabric of claim 3, wherein the at least one first cored yarn of the first layer and the at least one second cored yarn of the second layer are woven into warps and wefts.

5. The conductive fabric of claim 3, wherein the at least one first cored yarn of the first layer and the at least one second cored yarn of the second layer are woven in parallel.

6. The conductive fabric of claim 3, further comprising a plurality of third non-conductive threads for weaving the first layer and the second layer together.

7. The conductive fabric of claim 6, wherein the first non-conductive threads, the second non-conductive threads and the thirds threads are made from one or more components selected from the group consisting of polyester, PET, cotton, pure polyurethane polymer and their combinations.

8. The conductive fabric of claim 1, further comprising at least one insulation layer for covering one of the first layer and the second layer.

9. The conductive fabric of claim 1, wherein the at least one first conductive thread and the at least one second conductive thread are made by conductive fibers with electric conductivity.

10. The conductive fabric of claim 9, wherein the conductive fibers are made from one or more components selected from the group consisting of stainless steel fibers, carbon fibers, sputtered silver and their combinations.

11. A method for forming a conductive fabric, comprising:
weaving at least one first conductive thread within a plurality of first non-conductive threads to form a first layer with at least one first cored yarn;
weaving at least one second conductive thread within a plurality of second non-conductive threads to form a second layer with at least one second cored yarn; and
weaving the first layer and the second layer with a plurality of third non-conductive threads.

12. The method of claim 11, further comprising, providing at least one insulation layer for covering one of the first and the second layer.

13. A fabric circuit, comprising:
at least one electronic component; and
a conductive fabric, comprising:
a first layer, having at least one first conductive thread and a plurality of first non-conductive threads, wherein the at least one first conductive thread is woven within the plurality of first non-conductive threads; and
a second layer, having at least one second conductive thread and a plurality of second non-conductive threads, wherein the at least one second conductive thread is woven within the plurality of second non-conductive threads;
wherein the first layer is woven with the second layer and insulated from the second layer so that the at least one electronic component is attached to the conductive fabric and electrically connects to the at least one first conductive thread and the at least one second conductive thread.

14. The fabric circuit of claim 13, further comprising at least one conductive sewing thread.

15. The fabric circuit of claim 14, wherein each of the at least one electronic component has at least two leads for being sewed onto the conductive fabric by the at least one conductive sewing thread and each of the at least two leads of the electronic component electrically connects to the at least one first conductive thread and the at least one second conductive thread respectively.

16. The fabric circuit of claim 14, wherein the at least one electronic component is a light emitting diode, wherein the light emitting diode has two leads for being sewed onto the conductive fabric by the at least one conductive sewing thread and each of the two leads of the light emitting diode electrically connects to the at least one first conductive thread and the at least one second conductive thread respectively.

17. The fabric circuit of claim 13, wherein the first non-conductive threads comprise a first covering portion and the second non-conductive threads comprise a second covering portion, the at least one first conductive thread is covered by the first covering portion to form at least one first cored yarn and the at least one second conductive thread is covered by the second covering portion to form at least one second cored yarn.

18. The fabric circuit of claim 17, wherein the at least one first cored yarn of the first layer and the at least one second cored yarn of the second layer are woven into warps and wefts.

19. The fabric circuit of claim 18, wherein the at least one electronic component are attached to a position adjacent to a junction formed by the at least one first cored yarn intersecting the at least one second cored yarn.
